(19) United States
(12) Patent Application Publication
(10) Pub. No.: US 2010/0087030 A1
(43) Pub. Date: Apr. 8, 2010

(54) METHOD, APPARATUS AND SYSTEM OF MANUFACTURING SOLAR CELL

(75) Inventor: Joung-Sik Kim, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/597,169

(22) PCT Filed: May 9, 2008
(86) PCT No.: PCT/KR08/02625

§ 371 Date: Oct. 22, 2009

(30) Foreign Application Priority Data
May 11, 2007 (KR) 10-2007-0046138

(51) Int. Cl. H01L 31/18; H01L 21/3065; C23C 16/513

(52) U.S. Cl. 438/71; 156/345.33; 118/723 R; 257/E31.13

(57) ABSTRACT

A method of manufacturing a crystalline silicon solar cell includes steps of preparing a crystalline silicon substrate, texturing the substrate using plasma to form uneven patterns for increasing light absorption, doping ions in the substrate using plasma to form a doping layer for a PN junction, heating the substrate to activate the doped ions, forming an antireflection film on the doping layer, and forming front and back electrodes on front and back surfaces of the substrate, respectively.

### TECHNICAL FIELD

The present invention relates to a solar cell, and more particularly, to a method, an apparatus and a system of manufacturing a solar cell that increase productivity and decrease manufacturing costs by simplifying a manufacturing process of a crystalline silicon solar cell.

### BACKGROUND ART

Solar cells are devices that generate electromotive force from minor carriers, which are excited by sunlight, in P—N junction semiconductor devices. Single crystal silicon, polycrystalline silicon, amorphous silicon or compound semiconductors may be used for manufacturing the solar cells.

Single crystal silicon has the highest energy-converting efficiency. However, since single crystal silicon is expensive, polycrystalline silicon has been widely used. Recently, thin film solar cells have been widely used because they can be manufactured at small expense by depositing amorphous silicon or compound semiconductors on relatively cheap substrates, such as glass or plastic substrates.

Hereinafter, a manufacturing method of a crystalline silicon solar cell according to the related art will be described with reference to FIG. 1 and FIGS. 2 to 6.

FIG. 1 is a flow chart of illustrating a manufacturing process of a crystalline silicon solar cell according to the related art. FIGS. 2 to 6 are views of illustrating cross-sections in steps of manufacturing a crystalline silicon solar cell according to the related art.

Referring to FIG. 1 and FIG. 2, at step ST11, a crystalline silicon substrate 10 is prepared. Then, damages, which may be caused during a cutting process, are removed by wet etching using acids or bases. Here, the substrate 10 may be p-type, and an n-type substrate may be used.

At step ST12, a process of texturing a surface of the substrate 10 is performed to increase light absorption. During the texturing process, fine uneven patterns are formed on the surface of the substrate 10. The uneven patterns, desirably, may have pyramid shapes. In general, the texturing process may be performed by wet etching using acids or bases.

Referring to FIG. 1 and FIG. 3, at step ST13, n-type dopants are diffused in the p-type substrate 10 to form a P—N junction structure after the texturing process. A thermal diffusion method has been widely used. In the thermal diffusion method, the p-type substrate 10 is disposed in a diffusion furnace under high temperatures, and gases including n-type dopants such as POC13 or PH3 are provided. Then, the n-type dopants are diffused into the p-type substrate 10, and an n+ doping layer 12 is formed as shown in FIG. 3.

A diffusion process of step ST13 is performed under high temperatures over 800 degrees of Celsius, and residual products such as PSG (phosphor-silicate glass) may be formed on the surface of the substrate 10 due to the high temperatures. By the way, since PSG screens currents of a solar cell, PSG is removed by an etchant to increase an efficiency of the solar cell.

Therefore, at step ST14, PSG is removed.

Alternatively, if p-type dopants including boron (B) are diffused in an n-type substrate, BSG (boro-silicate glass) may be formed. BSG also decreases the efficiency of the electric cell, and BSG should be removed by the same method as PSG.

In the meantime, during the diffusion process of step ST13, the n+ doping layer 12 is formed on side edges of the substrate 10 too. Leakage currents may be generated between front and back electrodes through the doping layer 12 on the side edges of the substrate 10.

Accordingly, referring to FIG. 1 and FIG. 4, at step ST15, to improve the efficiency of the solar cell, the n+ doping layer 12 on the side edges of the substrate 10 is removed. This may be referred to as an edge isolation process.

More particularly, the n+ doping layer 12 on the side edges of the substrate 10 may be cut by a laser or may be etched by wet etching or dry etching. The edge isolation process may be performed before testing a completed solar cell.

Referring to FIG. 1 and FIG. 5, at step ST16, an anti-reflection film 14 is formed on the n+ doping layer 12. The anti-reflection film 14 may be formed of silicon nitride (SiNx). A SiNx layer not only increases absorption of sunlight but also functions as a surface passivation layer and a hydrogen passivation layer. The SiNx layer is formed by a plasma enhanced chemical vapor deposition (PECVD) method. The SiNx layer may be formed by a sputter method.

Referring to FIG. 1 and FIG. 6, at step ST17, electrodes are formed on front and back surfaces of the substrate 10 using a conductive material, respectively, after forming the anti-reflection film 14 of SiNx. To do this, conductive paste including aluminum (Al) or silver (Ag) is applied on the front and back surfaces of the substrate 10 by a screen printing method such that a predetermined pattern is formed. Then, a process of sintering the substrate 10 is performed in a furnace under high temperatures.

The conductive paste is sintered, and a front electrode 18 and a back electrode 16 are formed on the front and back surfaces of the substrate 10, respectively, as shown in FIG. 6.

Specially, if Al paste is applied on the back surface of the p-type substrate 10 and is sintered, Al is diffused into the n+ doping layer 12 during the sintering process, and a p+ layer 13 is formed. If the p+ layer 13 is formed on the back surface of the p-type substrate 10, a back surface field is induced at the back surface of the substrate 10.

The back surface field makes electrons, which are excited in the p-type substrate 10 by sunlight, move to the back electrode 16 due to and then move to the front electrode 18 without vanishing to contribute to photo currents and increase the efficiency of the solar cell.

At step ST18, after forming the electrodes, the efficiency of the solar cell is tested and is classified according to results of the test. Before testing, an edge isolation process cutting or etching edge portions of the substrate 10 may be performed to remove leakage currents at edges of the solar cell. Next, a solar cell module is fabricated through a module process for connecting a plurality of completed solar cells.

### DISCLOSURE OF INVENTION

### Technical Problem

However, the above-mentioned manufacturing process of the solar cell have the following several problems.

First, wet etching method is widely used during the texturing process of step ST12, and it is difficult to obtain uniform surface roughness because etch rates of polycrystalline silicon substrate may differ more than several ten times to several hundred times according to crystal faces.

Additionally, in the diffusion process of step ST13 for forming the P—N junction, since residual products such as PSG or BSG are formed, an additional process of removing the residual products is needed.

Moreover, in the diffusion process of step ST13, the conductive layer is formed on the edges of the substrate 10, and thus the edge isolation process is necessarily performed to prevent leakage currents from being induced between the front electrode and the back electrode.

The PSG- or BSG-removing process and the edge isolation process put a limitation on improving the productivity of the solar cells.

Meanwhile, it is not easy that a manufacturing system of a solar cell is designed as an integrated system or a continuous in-line system because the texturing process is generally performed by wet etching method and the diffusion process is carried out in a furnace under high temperatures.

Further, to carry the substrate into the diffusion furnace for performing the diffusion process under high temperatures, the substrate is transferred on the substrate support that is made of quartz. Accordingly, the productivity is lowered due to the transferring time.

Moreover, the thermal diffusion process is performed under high temperatures for a long time to obtain an enough junction depth. Thus, there is disadvantage in the productivity and it is difficult to control the junction depth.

### Technical Solution

Accordingly, the present invention is directed to a method of manufacturing a solar cell that simplifies a manufacturing process to increase productivity and reduce manufacturing costs.

Another object of the present invention is to provide an apparatus and a system of manufacturing a solar cell that are designed as an integrated structure or an in-line structure to increase productivity and decrease a footprint of the system.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method of manufacturing a crystalline silicon solar cell includes steps of preparing a crystalline silicon substrate, texturing the substrate using plasma to form uneven patterns for increasing light absorption, doping ions in the substrate using plasma to form a doping layer for a P—N junction, heating the substrate to activate the doped ions, forming an anti-reflection film on the doping layer, and forming front and back electrodes on front and back surfaces of the substrate, respectively.

In another aspect, an apparatus of manufacturing a crystalline silicon solar cell includes a chamber having a reaction space and including a chamber lid that is grounded, a substrate support in the chamber, a gas distribution plate disposed under the chamber lid and including a plurality of injection holes, a gas supply line passing through the chamber lid and supplying source gases to the gas distribution plate, and an RF power source connected to the substrate support, wherein a substrate loaded on the substrate support is textured to form uneven patterns on a surface of the substrate and then continuously is doped with ions by using plasma to form a P—N junction in the chamber.

In another aspect, a system of manufacturing a crystalline silicon solar cell includes a transfer chamber including a substrate-transferring means, a texturing chamber connected to the transfer chamber and texturing a substrate by using plasma to form uneven patterns, a plasma ion doping chamber connected to the transfer chamber and doping the textured substrate with ions by using plasma to form a P—N junction, and a loadlock chamber connected to the transfer chamber and being alternately under vacuum and atmospheric conditions for carrying the substrate in and out.

In another aspect, a system of manufacturing a crystalline silicon solar cell includes a loading chamber being alternately under vacuum and atmospheric conditions for carrying a substrate in, a texturing chamber connected to the loading chamber and texturing the substrate by using plasma to form uneven patterns on a surface of the substrate, a plasma ion doping chamber connected to the texturing chamber and doping the textured substrate with ions by using plasma to form a P—N junction, and an unloading chamber connected to the plasma ion doping chamber and being alternately under vacuum and atmospheric conditions for carrying the substrate out.

It is to be understood that both the foregoing general description and the following detailed description are exemplary and explanatory and are intended to provide further explanation of the invention as claimed.

### Advantageous Effects

According to the present invention, when a crystalline silicon solar cell is manufactured, the texturing process and the ion doping process may be performed in the same chamber or may be performed in respective chambers subsequently arranged. Thus, the footprint of the manufacturing system of a solar cell is decreased, and manufacturing costs are reduced.

In addition, since the texturing process is performed using plasma, uniform surface roughness can be obtained regardless of crystal faces of crystalline silicon, and the reproducibility of the texturing process is increased.

Moreover, the ion doping process is performed by using plasma under relatively low temperature, and there exist no residual products such as PSG or BSG. Accordingly, a step of removing the residual products is not required, and productivity is considerably increased.

Further, because ions normally incident on the substrate are doped, the edge isolation process can be omitted. Therefore, the productivity is considerably increased.

Additionally, the texturing process is performed by the dry etching method in place of the wet etching method in the related art, and expensive etchant is not necessary. Accodingly, manufacturing costs are decreased.

It will be apparent to those skilled in the art that various modifications and variations can be made without departing from the spirit or scope of the invention. Thus, it is intended that the present invention covers the modifications and variations of this invention provided they come within the scope of the appended claims and their equivalents.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a flow chart of illustrating a manufacturing process of a crystalline silicon solar cell according to the related art;

FIGS. 2 to 6 are views of illustrating cross-sections in steps of manufacturing a crystalline silicon solar cell according to the related art;

FIG. 7 is a flow chart of illustrating a manufacturing process of a crystalline silicon solar cell according to an exemplary embodiment of the present invention;

FIGS. 8 to 13 are views of illustrating cross-sections in steps of manufacturing a crystalline silicon solar cell according to an exemplary embodiment of the present invention;

FIG. 14 is a view of illustrating an RIE apparatus for texturing according to the present invention;

FIG. 15 is a view of illustrating a plasma ion doping apparatus according to the present invention;

FIG. 16 is a view of illustrating a manufacturing system of a solar cell according to an exemplary embodiment of the present invention; and

FIG. 17 is a view of illustrating a manufacturing system of a solar cell according to another embodiment of the present invention.

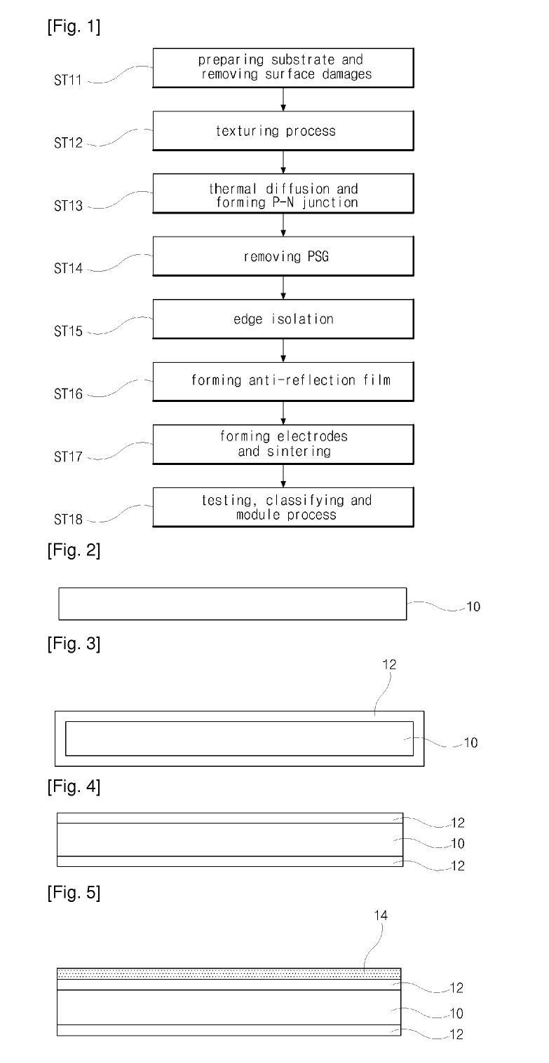

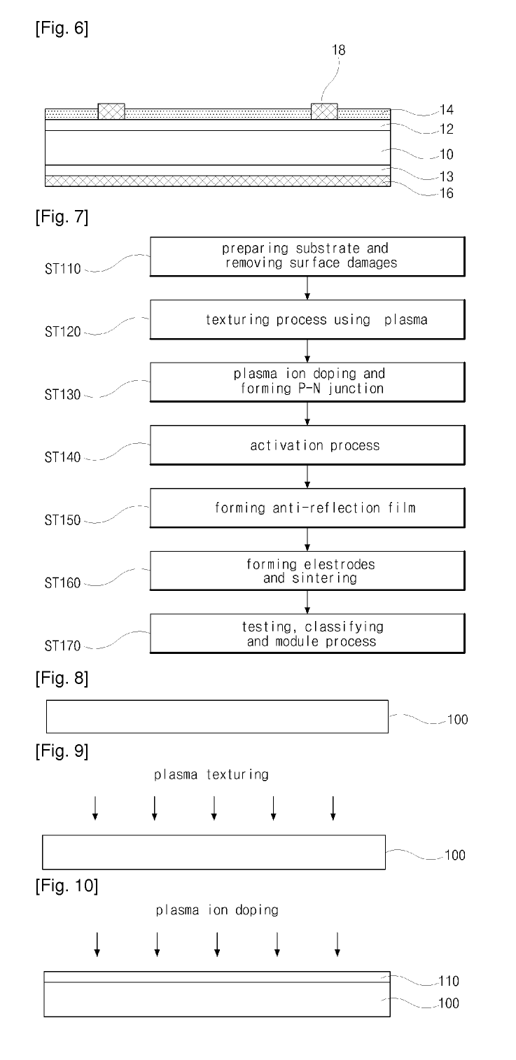

### BEST MODE FOR CARRYING OUT THE INVENTION

Reference will now be made in detail to the preferred exemplary embodiments, examples of which are illustrated in the accompanying drawings.

A manufacturing method of a crystalline silicon solar cell according to the present invention will be described with reference to FIG. 7 and FIGS. 8 to 13.

FIG. 7 is a flow chart of illustrating a manufacturing process of a crystalline silicon solar cell according to an exemplary embodiment of the present invention. FIGS. 8 to 13 are views of illustrating cross-sections in steps of manufacturing a crystalline silicon solar cell according to an exemplary embodiment of the present invention.

Referring to FIG. 7 and FIG. 8, at step ST110, a crystalline silicon substrate 100 is prepared. Then, damages, which may be caused during a cutting process, are removed by wet etching using acids or bases. Here, the substrate 100 may be p-type, and an n-type substrate may be used.

Referring to FIG. 7 and FIG. 9, at step ST120, a process of texturing a surface of the substrate 100 is performed to increase light absorption. In the present invention differently from the related art, the surface of the substrate 100 is textured by reactive ion etching (RIE) using plasma.

FIG. 14 is a view of illustrating an RIE apparatus for texturing according to the present invention. In FIG. 14, the RIE apparatus 200 includes a chamber 210 having a reaction space, a substrate support 220 in the chamber 210, a gas distribution plate 230 disposed under and spaced apart from a chamber lid 212, and a gas supply line 250 passing through the chamber lid 212 and supplying source gases to the gas distribution plate 230. The gas distribution plate 230 may be connected to a lower portion of the chamber lid 212.

The substrate support 220 and the gas distribution plate 230, desirably, are formed of anodized aluminum. An exhaust port 214 is set up at a lower part of the chamber 210 to exhaust remaining gases and keep vacuum pressure.

The chamber lid 212, which is electrically connected to the gas distribution plate 230, is grounded. The substrate support 220 is connected to an RF power source 260 for providing RF power. An impedance matching unit 262 for matching impedance between the RF power source 260 and the substrate support 220.

To performing the texturing process in the RIE apparatus 200, the p-type substrate 100 is carried into the chamber 210 and is loaded on the substrate support 220.

Here, the substrate 100 may be directly located on the substrate support 220. To increase the productivity, a tray (not shown) on which a plurality of substrates 100 are disposed may be brought in the chamber 210, and the process may be performed. At this time, a means for locating the tray (not shown) thereon may be set up in the chamber 210.

Next, vacuum pumping is carried out through the exhaust port 214, and process pressure is set up. One or more of etching gases, such as Cl₂, SF₆, O₂, etc., are injected to an upper portion of the substrate support 220 by the gas distribution plate 230. RF power of 13.56 MHz, for example, is applied to the substrate support 220 from the RF power source 260.

When the RF power is applied to the substrate support 220, RF electric field is induced between the substrate support 220 and the grounded chamber lid 212. Electrons accelerated by the RF electric field collide with neutral gases, and plasma, which is a mixture of ions, electrons and radicals, is formed.

Here, ions is accelerated by the RF electric field and collide with the surface of the substrate 100. Therefore, the surface of the substrate 100 is textured.

In texturing using the RIE apparatus 200, even though a crystalline silicon substrate has various crystal faces, uniform surface roughness can be obtained on a surface of the crystalline silicon substrate. According, reproducibility of the texturing process is considerably increased.

On the other hand, before texturing the substrate 100 in the RIE apparatus 200, a process of removing surface damages of the substrate 100 may be performed in the same chamber as the RIE apparatus 200.

Referring to FIG. 7 and FIG. 10, at step ST130, n-type dopants are diffused in the p-type substrate 10 to form a P—N junction structure after the texturing process. While a thermal diffusion method has been widely used in the related art, an ion doping method using plasma is used in the present invention.

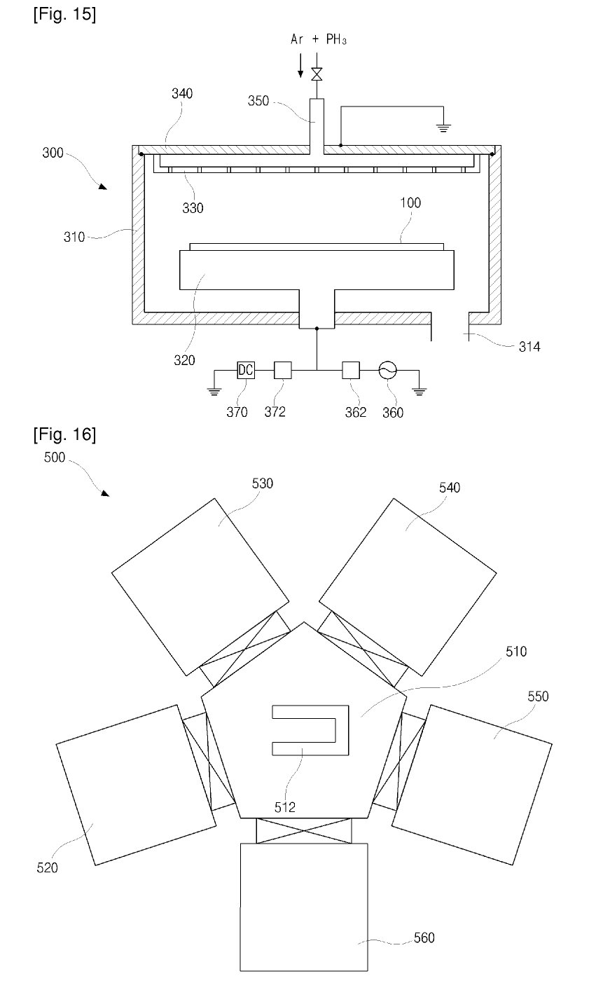

FIG. 15 is a view of illustrating a plasma ion doping apparatus according to the present invention. In FIG. 15, the plasma ion doping apparatus 300 includes a chamber 310 having a reaction space, a substrate support 320 in the chamber 310, a gas distribution plate 330 disposed under and spaced apart from a chamber lid 340 for sealing up an upper part of the chamber 310, and a gas supply line 350 passing through the chamber lid 340 and supplying gases to the gas distribution plate 330.

Beneficially, the substrate support 320 and the gas distribution plate 330 are formed of anodized aluminum. An exhaust port 314 is set up at a lower part of the chamber 310 to exhaust remaining gases and keep vacuum pressure.

The chamber lid 340, which is electrically connected to the gas distribution plate 330, is grounded. The substrate support 320 is connected to an RF power source 360 for providing RF power.

Especially, it is desirable that the substrate support 320 is further connected to a DC power source 370 to increase incident energies of ions generated by the RF power and improve doping efficiency.

At this time, a high pass filter (HPF) 362, beneficially, is disposed between the RF power source 360 and the substrate support 320 to prevent effects on the RF power source 360 by DC power. In addition, a low pass filter (LPF) 372, desirably, is disposed between the DC power source 370 and the substrate support 320 to prevent effects on the DC power source 370 by the RF power.

An impedance matching unit (not shown) for matching impedance between the RF power source 360 and the substrate support 320.

To perform the ion doping process in the plasma ion doping apparatus 300, the p-type substrate 100 is carried into the chamber 310 and is loaded on the substrate support 320.

Here, the substrate 100 may be directly located on the substrate support 320. To increase the productivity, a tray (not shown) on which a plurality of substrates 100 are disposed may be brought in the chamber 310, and the process may be performed. At this time, a means for locating the tray (not shown) thereon may be set up in the chamber 310.

Next, vacuum pumping is carried out through the exhaust port 314, and process pressure is set up. Gases including phosphorus (P) as an n-type dopant are injected to an upper portion of the substrate support 320 by the gas distribution plate 330. For example, the gases including P may be phosphorus hydride (PH3). In addition, argon (Ar) gas may be added. Alternatively, if an n-type substrate is used, gases including boron (B) as a p-type dopant may be injected.

RF power of 13.56 MHz and DC power, for example, are simultaneously applied to the substrate support 320 from the RF power source 360 and the DC power source 370. The frequency of the RF power is not limited to the above-mentioned value, and other RF power of commonly used frequencies can be applied.

When the RF power is applied to the substrate support 320, RF electric field is induced between the substrate support 320 and the grounded chamber lid 330, and plasma is formed. At this time, p+ ions in the plasma are accelerated by the RF electric field and are incident the surface of the substrate 100. Therefore, ion doping is carried out on the p-type substrate 100.

Here, the DC power applied to the substrate support 320 from the DC power source 370 increases incident energies of ions generated by the RF power and improves doping efficiency.

In the plasma ion doping method as mentioned above, since doping density or P—N junction depth can be relatively accurately controlled by adjusting gas flow rates or the RF power, more precise and higher reproducible process can be performed than the thermal diffusion method.

Moreover, the plasma ion doping is performed under relatively low temperature, and there exists no PSG or BSG as residual products of the thermal diffusion process. Accordingly, a step of removing the residual products is not required, and the plasma ion doping method is advantageous in productivity.

Further, there is no n+ doing layer on side edges of the substrate 100 differently from the thermal diffusion method because ions normally incident with respect to the surface of the substrate 100 are doped. Therefore, an edge isolation process for preventing leakage currents is not necessary, and productivity is increased.

In the meantime, the plasma ion doping apparatus 300 of FIG. 15 has a similar structure to the texturing apparatus 200 of FIG. 14. Thus, it is possible that the texturing process and the plasma ion doping process are subsequently performed in the plasma ion doping apparatus of FIG. 15.

Actually, since RF power of 13.56 MHz is commonly applied to the substrate supports 220 and 320 of the texturing apparatus 200 and the plasma ion doping apparatus 300 in respective processes, the texturing process and the plasma ion doping process can be subsequently performed in the plasma ion doping apparatus of FIG. 15.

To do this, the DC power source 370 may be off during the texturing process, and the DC power source 370 may be on during the plasma ion doping process.

In addition, because gases supplied through the gas supply line 350 are different in respective processes, an additional gas supply line is needed, and enough exhausting time is necessary between the processes to prevent the gases from being mixed.

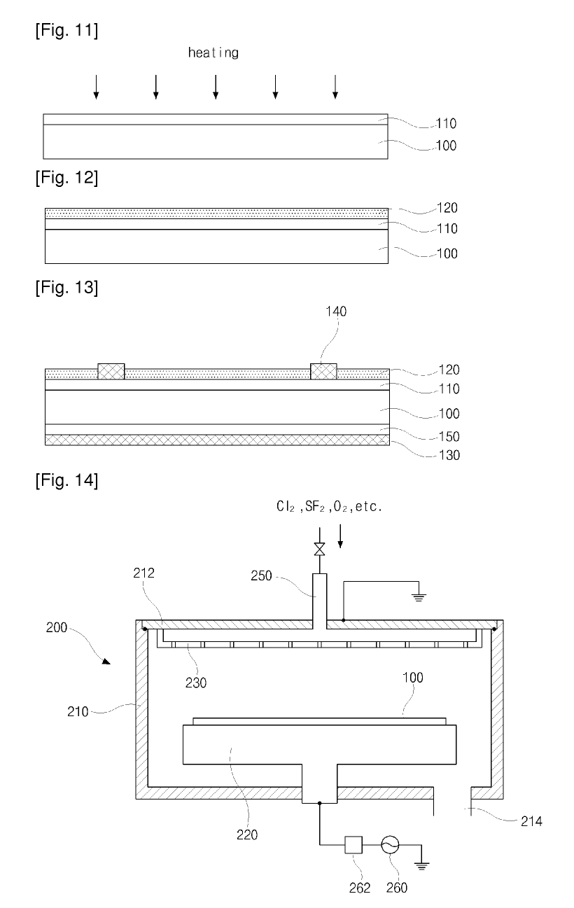

Referring to FIG. 7 and FIG. 11, at step ST140, an activation process is performed after ion doping the p-type substrate 100 using plasma according to the above-mentioned method, and the substrate 100 is heated under predetermined temperatures.

In the activation process, the doped ions are activated by supplying additional energy to the substrate 100 such that the doped ions are combined with silicon (Si). The doped ions may function as impurities without the activation process.

Additionally, there may be an effect of preheating the substrate 100, which is necessary for depositing an anti-reflection film by a PECVD method later, through the activation process.

It is desirable that the activation process is performed in an additional activation chamber, which includes an optical heat means such as a lamp heater or includes a substrate support with a heater such as resistance coil therein. Heating temperatures and time can be changes according to doped materials or degrees of activation.

Referring to FIG. 7 and FIG. 12, at step ST150, after ion doping of the p-type substrate 100 is performed and the substrate 100 is preheated through the above-mentioned processes, an anti-reflection film 120 is formed on the n+ doping layer 110. The anti-reflection film 120 may be a silicon nitride (SiNx) layer deposited by a PECVD method.

Referring to FIG. 7 and FIG. 13, at step ST160, electrodes are formed on front and back surfaces of the substrate 100 using a conductive material, respectively, after forming the anti-reflection film 120 of SiNx. To do this, conductive paste including aluminum (Al) or silver (Ag) is applied on the front and back surfaces of the substrate 100 by a screen printing method such that a predetermined pattern is formed. Then, a process of sintering the substrate 100 is performed in a furnace under high temperatures.

The conductive paste is sintered, and a front electrode 18 and a back electrode 16 are formed on the front and back surfaces of the substrate 10, respectively.

For example, when Al paste is applied on the back surface of the p-type substrate 100 and is sintered, Al is diffused into the substrate 100 during the sintering process, and a p+ layer 150 is formed. Therefore, a back surface field is induced at the back surface of the substrate 100. The back surface field has the same functions as mentioned above.

Referring to FIG. 7, at step ST170, after forming the electrodes, the efficiency of the solar cell is tested and is classified according to results of the test. Next, a solar cell module is fabricated through a module process for connecting a plurality of completed solar cells.

In the meantime, to manufacture a crystalline silicon solar cell according to the exemplary embodiment of the present invention, each process apparatus may be set up efficiently considering productivity and footprints.

As stated above, it is possible that the texturing process is performed in the plasma ion doping apparatus 300. However, there is a limitation on combining respective process apparatuses because process conditions of respective processes are different.

Accordingly, it is important to design a manufacturing system of a solar cell such that time for transferring the substrate between processes is minimized and the whole footprint is decreased.

### MODE FOR THE INVENTION

FIG. 16 is a view of illustrating a manufacturing system of a solar cell according to an exemplary embodiment of the present invention. In FIG. 16, the manufacturing system of a solar cell includes a transfer chamber 510 for transferring a substrate and further includes a loadlock chamber 520, a texturing chamber 530, a plasma ion doping chamber 540, an activation chamber 550 and an anti-reflection film deposition chamber 560 connected to respective side portions of the transfer chamber 510.

A slot valve is set up between the transfer chamber 510 and each chamber 520, 530, 540, 550 or 560 to selectively open a gateway.

In the manufacturing method of a solar cell according to the present invention, the texturing process, the ion doping process and the anti-reflection film depositing process are performed using plasma under predetermined vacuum pressures.

Therefore, the texturing chamber 530, the plasma ion doping chamber 540 and the anti-reflection film deposition chamber 560 are connected to the transfer chamber 510, which is always under vacuum, and time for transferring a substrate or vacuum pumping is considerably decreased.

The activation chamber 550 not only heats the substrate to provide activation energy to ions doped in the plasma ion doping chamber 540 but also preheats the substrate before depositing an anti-reflection film.

For consecutive processes, the activation chamber 550, beneficially, is disposed between the plasma ion doping chamber 540 and the anti-reflection film deposition chamber 560.

The substrate is carried in and/or out through the loadlock chamber 520 from the exterior. Thus, the loadlock chamber 520 is alternately under vacuum and atmosphere condition.

A transfer robot 512 is set up in the transfer chamber 510 to transfer the substrate.

When the substrate is carried into the loadlock chamber 520 from the exterior, the transfer robot 512 transfers the substrate into the texturing chamber 530 from the loadlock chamber 520, into the plasma ion doping chamber 540 after the texturing process, into the activation chamber 550 after the plasma ion doping process, into the anti-reflection film deposition chamber 560 after the activation process, and into the loadlock chamber 520 again after depositing the anti-reflection film.

The manufacturing system of a solar cell illustrated in FIG. 16 is an example. Only the loadlock chamber 520, the texturing chamber 530 and the plasma ion doping chamber 540 are connected to the transfer chamber 510, and the activation chamber 550 and the anti-reflection film deposition chamber 560 may be omitted. In addition, to increase efficiency of exchanging substrates, more than two loadlock chambers 520 may be set up.

Further, in addition to the texturing chamber 530, the plasma ion doping chamber 540, the activation chamber 550 and the anti-reflection film deposition chamber 560, a process chamber of forming a contact hole for an electrode or applying electrode paste may be connected to a side portion of the transfer chamber 510.

Meanwhile, transferring the substrate may be performed by the transfer robot 512 by a piece or by a tray (not shown) carrying a plurality of substrates.

When the tray is used, the tray may be transferred into the loadlock chamber, the texturing chamber, the plasma ion doping chamber, the activation chamber and the anti-reflection film deposition chamber in order.

The substrate or the tray may be transferred by a transfer robot, which lifts and transfer the substrate or the tray, or may be transferred by an in-line method using a roller or linear motor. In the latter, the means may be also set up in each chamber.

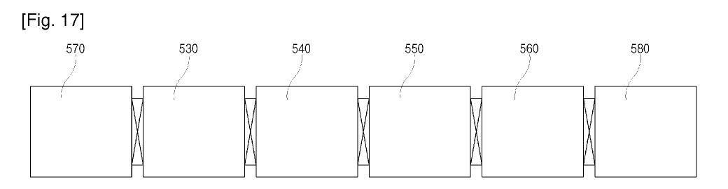

FIG. 17 is a view of illustrating a manufacturing system of a solar cell according to another embodiment of the present invention. In the manufacturing system of a solar cell of FIG. 17, a substrate or tray is transferred by an in-line method.

More particularly, the manufacturing system of a solar cell of FIG. 17 includes a loading chamber 570 for carrying the substrate or tray into the system from the exterior and an unloading chamber 580 for carrying the substrate or tray out of the system. A texturing chamber 530, a plasma ion doping chamber 540, an activation chamber 550 and an anti-reflection film deposition chamber 560 are set up between the loading chamber 570 and the unloading chamber 580 according to a process order.

Functions of the chambers are the same as those of FIG. 16, and explanation for the functions will be omitted.

After a substrate or tray including a plurality of substrates is supplied in the loading chamber 570 from the exterior, the substrate or tray may pass through and be processed in the texturing chamber 530, the plasma ion doping chamber 540, the activation chamber 550 and the anti-reflection film deposition chamber 560 in order, and then the substrate or tray may be carried out through the unloading chamber 580.

Here, only the texturing chamber 530 and the plasma ion doping chamber 540 may be set up between the loading chamber 570 and the unloading chamber 580, and the activation chamber 550 and the anti-reflection film deposition chamber 560 may be separately set up.

A transferring means of an in-line method, for example, a roller or a linear motor, is set up in each chamber to transfer the substrate or tray into a neighboring chamber.

In addition, a slot valve is set up between adjacent chambers to selectively open a gateway.

In the in-line type manufacturing system of a solar cell, the transfer robot, which is expensive, can be omitted, and costs of the system may be decreased. Since the in-line manufacturing system of a solar cell can be set up in a straight space, where a cluster-type system is difficult to be set up, spaces can be effectively used.

In the present invention, the solar cell is manufactured by doping n-type dopants into the p-type substrate. Alternatively, the solar cell may be manufactured by doping p-type dopants into an n-type substrate.

1. A method of manufacturing a crystalline silicon solar cell, comprising:
preparing a crystalline silicon substrate;
texturing the substrate using plasma to form uneven patterns at a surface of the substrate;
doping ions in the substrate with the uneven patterns using plasma to form a doping layer for a P—N junction;
heating the substrate to activate the doped ions;
forming an anti-reflection film on the doping layer; and
forming front and back electrodes on front and back surfaces of the substrate, respectively.

2. The method according to claim 1, wherein texturing the substrate using plasma includes injecting at least one etching gas selected from Cl₂, SF₆, and O₂ to form the plasma.

3. The method according to claim 1, wherein doping ions in the substrate using plasma includes injecting dopants onto the substrate to form the plasma.

4. The method according to claim 1, wherein texturing the substrate using plasma and doping ions in the substrate using plasma are performed in a same chamber.

5. The method according to claim 1, wherein the anti-reflection film includes a silicon nitride layer deposited by a plasma enhanced chemical vapor deposition method.

6. The method according to claim 1, further comprising removing damages on surfaces of the substrate before texturing the substrate using plasma, wherein texturing the substrate using plasma and removing damages on surfaces of the substrate are performed in a same chamber.

7. An apparatus of manufacturing a crystalline silicon solar cell, comprising:
a chamber having a reaction space and including a chamber lid that is grounded;
a substrate support in the chamber;
a gas distribution plate disposed under the chamber lid and including a plurality of injection holes;
a gas supply line passing through the chamber lid and supplying source gases to the gas distribution plate; and
an RF power source connected to the substrate support,
wherein a substrate loaded on the substrate support is textured to form uneven patterns on a surface of the substrate and then continuously is doped with ions by using plasma to form a P—N junction in the chamber.

8. The apparatus according to claim 7, further comprising a DC power source connected to the substrate support, wherein the DC power source supplies a DC power to the substrate support only when the substrate is doped with ions.

9. The apparatus according to claim 8, wherein a first filter is disposed between the RF power source and the substrate support, and a second filter is disposed between the DC power source and the substrate support, wherein the second filter passes lower frequency than the first filter.

10. A system of manufacturing a crystalline silicon solar cell, comprising:
a transfer chamber including a substrate-transferring means;
a texturing chamber connected to the transfer chamber and texturing a substrate by using plasma to form uneven patterns;
a plasma ion doping chamber connected to the transfer chamber and doping the textured substrate with ions by using plasma to form a P—N junction; and
a loadlock chamber connected to the transfer chamber and being alternately under vacuum and atmospheric conditions for carrying the substrate in and out.

11. The system according to claim 10, further comprising an activation chamber connected to the transfer chamber and heating the substrate to activate ions doped in the plasma ion doping chamber.

12. The system according to claim 11, further comprising an anti-reflection film deposition chamber connected to the transfer chamber and forming an anti-reflection film on a surface of the substrate activated in the activation chamber.

13. The system according to claim 10, wherein a plurality of substrates are transferred between the texturing chamber and the plasma ion doping chamber through a tray carrying the plurality of substrates, and the plurality of substrates carried by the tray are processed in the texturing chamber and the plasma ion doping chamber.

14. A system of manufacturing a crystalline silicon solar cell, comprising:
a loading chamber being alternately under vacuum and atmospheric conditions for carrying a substrate in;
a texturing chamber connected to the loading chamber and texturing the substrate by using plasma to form uneven patterns on a surface of the substrate;
a plasma ion doping chamber connected to the texturing chamber and doping the textured substrate with ions by using plasma to form a P—N junction; and
an unloading chamber connected to the plasma ion doping chamber and being alternately under vacuum and atmospheric conditions for carrying the substrate out.

15. The system according to claim 14, further comprising an activation chamber between the plasma ion doping chamber and the unloading chamber and heating the substrate to activate ions doped in the plasma ion doping chamber.

16. The system according to claim 15, further comprising an anti-reflection film deposition chamber between the activation chamber and the unloading chamber and forming an anti-reflection film on the surface of the substrate activated in the activation chamber.
